(19) United States
(12) Patent Application Publication
(10) Pub. No.: US 2026/0025146 A1
(43) Pub. Date: Jan. 22, 2026

(54) METHOD FOR DETECTING INTERSTAGE GAIN ERROR OF PIPELINED ANALOG-TO-DIGITAL CONVERTER WITH INFINITE PRECISION, AND ASSOCIATED APPARATUS

(71) Applicant: MEDIATEK INC., Hsinchu City (TW)

(72) Inventors: Henry Arnold Park, San Jose, CA (US); Tamer Mohammed Ali, San Jose, CA (US)

(73) Assignee: MEDIATEK INC., Hsinchu City (TW)

(21) Appl. No.: 19/270,505

(22) Filed: Jul. 16, 2025

Related U.S. Application Data
(60) Provisional application No. 63/673,933, filed on Jul. 22, 2024.

(51) Int. Cl. H03M 1/10; H03M 1/06

(52) U.S. Cl. CPC H03M 1/1071; H03M 1/0604

(57) ABSTRACT

A method for detecting interstage gain error of pipelined analog-to-digital converter (ADC) with infinite precision and an associated apparatus such as a detection circuit are provided. For any stage among multiple stages in a pipeline of the pipelined ADC, the detection circuit may include multiple circuit units of predetermined circuit elements, with each predetermined circuit element being an identical element which is identical to a series of predetermined elements belonging to a predetermined element type within the any stage. During coupling the predetermined circuit elements to an input node and an output node of an amplifier in turn, analog multiplexing circuits respectively integrated into the multiple circuit units may control signal paths of the predetermined circuit elements by coupling only one of the predetermined circuit elements to the input node of the amplifier while coupling remaining predetermined circuit elements to the output node of the amplifier at the same time.

### CROSS REFERENCE TO RELATED APPLICATIONS

This application claims the benefit of U.S. Provisional Application No. 63/673,933, filed on Jul. 22, 2024. The content of the application is incorporated herein by reference.

### BACKGROUND

The present invention is related to signal processing, and more particularly, to a method for detecting an interstage gain error of a pipelined analog-to-digital converter (ADC) with infinite precision, and an associated apparatus such as a detection circuit.

According to the related art, interstage gain error detection may be performed according to a detection algorithm, with associated operations such as correlator signal injection at one stage and subtracting a linearly scaled signal at the next stage, and finding out the correlation between the ADC output and the correlator signal, but some problems may occur. The main problem is that this detection algorithm may heavily depend on the matching of two injection signals. When trying to increase the accuracy of the associated measurements, there may be more problems such as area penalty and speed penalty. Thus, a novel method and associated architecture are needed for solving the problems without introducing any side effect or in a way that is less likely to introduce a side effect.

### SUMMARY

It is an objective of the present invention to provide a method for detecting an interstage gain error of a pipelined ADC with infinite precision, and an associated apparatus such as a detection circuit, in order to solve the above-mentioned problems.

At least one embodiment of the present invention provides a method for detecting an interstage gain error of a pipelined ADC with infinite precision, where the pipelined ADC may comprise multiple stages in a pipeline of the pipelined ADC. For example, the method may comprise: for any stage among the multiple stages, utilizing multiple circuit units of predetermined circuit elements, with each predetermined circuit element being an identical element which is identical to a series of predetermined elements belonging to a predetermined element type within the any stage, to start coupling the predetermined circuit elements to an input node and an output node of an amplifier, the amplifier coupled between the any stage and another stage, in turn; and during coupling the predetermined circuit elements to the input node and the output node of the amplifier in turn, utilizing multiple analog multiplexing circuits respectively integrated into the multiple circuit units, with each analog multiplexing circuit comprising at least one analog multiplexer (MUX) coupled with a corresponding predetermined circuit element among the predetermined circuit elements in series, to control signal paths of the predetermined circuit elements by coupling one of the predetermined circuit elements to the input node of the amplifier while coupling remaining predetermined circuit elements among the predetermined circuit elements to the output node of the amplifier at a same time point among multiple time points, for detecting the interstage gain error according to circuit element configurations corresponding to the multiple time points, wherein the predetermined circuit elements act as the one of the predetermined circuit elements at the multiple time points, respectively.

At least one embodiment of the present invention provides a detection circuit for detecting an interstage gain error of a pipelined ADC with infinite precision, where the pipelined ADC may comprise multiple stages in a pipeline of the pipelined ADC. For any stage among the multiple stages, the detection circuit may comprise multiple circuit units of predetermined circuit elements. The multiple circuit units may comprise the predetermined circuit elements, with each predetermined circuit element being an identical element which is identical to a series of predetermined elements belonging to a predetermined element type within the any stage, and further comprise multiple analog multiplexing circuits respectively integrated into the multiple circuit units, with each analog multiplexing circuit comprising at least one analog MUX coupled with a corresponding predetermined circuit element among the predetermined circuit elements in series. In addition, for the any stage among the multiple stages, the multiple circuit units may be arranged to start coupling the predetermined circuit elements to an input node and an output node of an amplifier, the amplifier coupled between the any stage and another stage, in turn. During coupling the predetermined circuit elements to the input node and the output node of the amplifier in turn, the multiple analog multiplexing circuits are arranged to control signal paths of the predetermined circuit elements by coupling one of the predetermined circuit elements to the input node of the amplifier while coupling remaining predetermined circuit elements among the predetermined circuit elements to the output node of the amplifier at a same time point among multiple time points, for detecting the interstage gain error according to circuit element configurations corresponding to the multiple time points, wherein the predetermined circuit elements act as the one of the predetermined circuit elements at the multiple time points, respectively.

According to some embodiments, the pipelined ADC is a pipelined successive approximation register (SAR) ADC, and the any stage among the multiple stages comprises a SAR ADC, where the series of predetermined elements is within the SAR ADC of the any stage. More particularly, the SAR ADC of the aforementioned any stage comprises an ADC and a digital-to-analog converter (DAC), where the series of predetermined elements is within the DAC. For example, the series of predetermined elements represents a series of DAC elements, the predetermined element type represents a predetermined DAC element type, and the aforementioned each predetermined circuit element is an identical DAC element which is identical to the series of DAC elements belonging to the predetermined DAC element type within the any stage.

It is an advantage of the present invention that, the method of the present invention, as well as the associated apparatus such as the detection circuit, can accurately detect the interstage gain error of the pipelined ADC. In addition, the method of the present invention, as well as the associated apparatus such as the detection circuit, can solve the related art problems without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates, in the lower half part thereof, an infinite-precision detection control scheme of a method for detecting an interstage gain error of a pipelined ADC with infinite precision according to an embodiment of the present invention, where a limited-precision detection control scheme is illustrated in the upper half part of FIG. 1 for better comprehension.

FIG. 2 illustrates multiple predetermined selection signals involved with the infinite-precision detection according to an embodiment of the present invention.

FIG. 3 illustrates a digital signal processing (DSP) circuit involved with the infinite-precision detection according to an embodiment of the present invention.

FIG. 4A illustrates a zeroth phase among multiple phases of an analog chopping control scheme of the method according to an embodiment of the present invention.

FIG. 4B illustrates a first phase among the multiple phases of the analog chopping control scheme.

FIG. 4C illustrates an N-th phase among the multiple phases of the analog chopping control scheme.

FIG. 5 illustrates, in the sub-diagram (d) thereof, a detection circuit involved with the method according to an embodiment of the present invention, where some examples of an identical DAC element used by a DAC unit among multiple DAC units of the detection circuit are illustrated in the sub-diagrams (a), (b), and (c) of FIG. 5 for better comprehension.

FIG. 6 illustrates a flowchart of the method according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

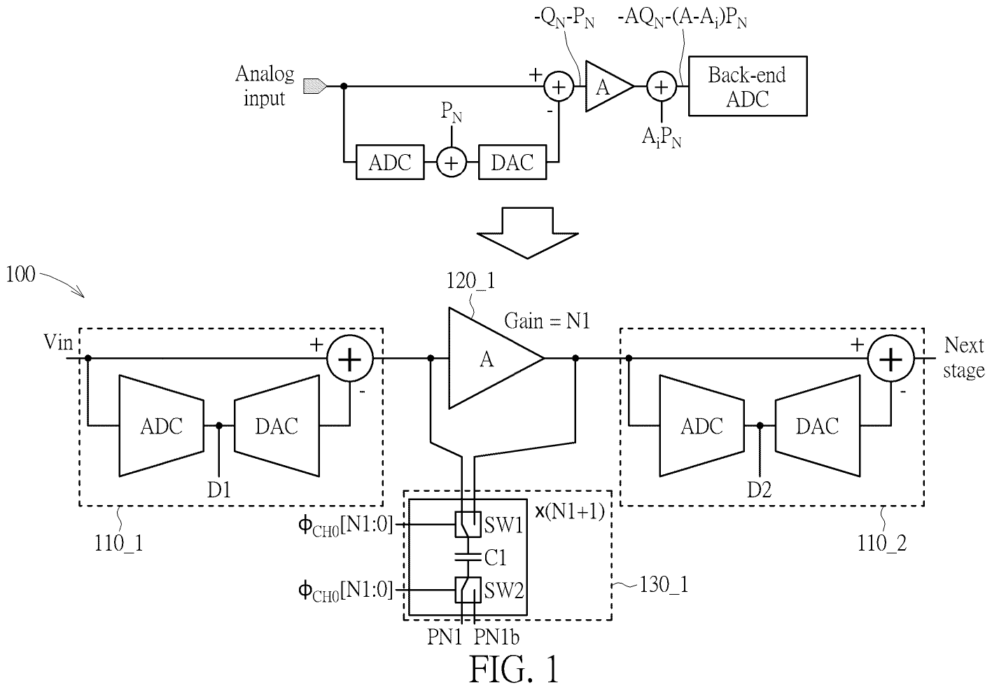

FIG. 1 illustrates, in the lower half part thereof, an infinite-precision detection control scheme of a method for detecting an interstage gain error of a pipelined ADC with infinite precision according to an embodiment of the present invention, where a limited-precision detection control scheme is illustrated in the upper half part of FIG. 1 for better comprehension. Based on the limited-precision detection control scheme, the interstage gain error detection may be done by a correlator signal P_{N} injection at one stage and subtracting a linearly scaled signal (A*P_{N}) at the next stage. By finding out the correlation between the ADC output and the correlator signal P_{N}, the interstage gain error may be detected. Regarding the associated implementation details, please refer to Bob Verbruggen, “A 2.1 mW 11b 410 MS/s Dynamic Pipelined SAR ADC with Background Calibration in 28 nm Digital CMOS”, 2013 Symposium on VLSI Circuits Digest of Technical Papers (“Verbruggen” hereinafter), the entirety of which is incorporated herein by reference. The limited-precision detection control scheme may heavily depend on the matching of two injection signals such as the correlator signal P_{N} and the linearly scaled signal (Aᵢ*P_{N}). For example, the gain A (or “the real gain A”) of the amplifier may be expressed with the summation (Aᵢ+ΔAᵢ) of the ideal gain Aᵢ and the gain error ΔAᵢ of the amplifier. When trying to increase the accuracy of the associated measurements, there may be more problems such as area and speed penalties. If the capacitors used for the associated measurements are implemented to have greater capacitance values, there may be severe area and speed penalties. A pipelined ADC 100 can operate according to the method (or at least one control scheme thereof such as the infinite-precision detection control scheme) in order to enhance the overall performance.

Assuming that “K” may represent a positive integer greater than one and that “k” may be an integer within the interval [1, K], the pipelined ADC 100 operating according to the infinite-precision detection control scheme may comprise multiple stages {110_k} such as the stages {110_k|k=1, 2, . . . , K} in a pipeline (or pipeline architecture) of the pipelined ADC 100. As shown in FIG. 1, the multiple stages {110_k} such as the stages {110_k|k=1, 2, . . . , K} may be illustrated as the stages {110_1, 110_2, . . . }, and the next stage coming after the stage 110_2 as well as one or more subsequent stages (if exist) may be omitted for brevity, but the present invention is not limited thereto. In some examples, more stages such as the next stage and the one or more subsequent stages may be illustrated in the pipeline architecture of the pipelined ADC 100. In addition, the pipelined ADC 100 may be a pipelined SAR ADC (or “SARADC”), and any stage 110_k among the multiple stages {110_k} may comprise a SAR ADC. The SAR ADC in the aforementioned any stage 110_k among the multiple stages {110_k} may comprise an ADC and a DAC corresponding to the stage index k, as well as a digital code output terminal between the ADC and the DAC corresponding to the stage index k, for outputting a digital code D(k) of this SAR ADC. For example, when k=1, the digital code D(k) of the SAR ADC in the stage 110_1 may represent the digital code D(1) (or “D1” for brevity); when k=2, the digital code D(k) of the SAR ADC in the stage 110_2 may represent the digital code D(2) (or “D2” for brevity); and the rest can be deduced by analogy.

In comparison with the architecture of the limited-precision detection control scheme, the aforementioned any stage 110_k (e.g., the stage 110_1) in the pipelined ADC 100 implemented according to the infinite-precision detection control scheme still comprises an arithmetic circuit (which may be illustrated with a circle labeled “+” therein for brevity) corresponding to the stage index k, having a positive input terminal and a negative input terminal (respectively labeled “+” and “−” outside the circle for brevity), for subtracting the output of the DAC from the input of the ADC within the stage 110_k (e.g., the stage 110_1) in order to generate a residue at the output of the stage 110_k, and the pipelined ADC 100 may still comprise an amplifier 120_k (e.g., the amplifier 120_1) that is coupled to the aforementioned any stage 110_k (e.g., the stage 110_1) to act as an interstage amplifier between the two consecutive stages 110_k and 110_(k+1) (e.g., the two stages 110_1 and 110_2), for receiving the residue from the output of the stage 110_k and amplifying this residue to generate the amplified residue, for being input into the latter stage 110_(k+1) (e.g., the stage 110_2) among the two consecutive stages 110_k and 110_(k+1). As the pipelined ADC 100 may comprise a more complicated detection architecture for detecting the interstage gain error with infinite precision, the amplification of the amplifier 120_k (e.g., the amplifier 120_1) will be very accurate, without any problem such as the problems due to inaccurate amplification in the related art.

The aforementioned more complicated detection architecture of the pipelined ADC 100 may comprise one or more detection circuits for detecting the interstage gain error(s) of the amplifier(s) {120_k|k=1 . . . (K−1)} in the pipeline of the pipelined ADC 100, such as the interstage gain error detection circuit corresponding to the stage index k (or “the k-th detection circuit”) that is coupled to both nodes among the input node and the output node of the amplifier 120_k (e.g., the amplifier 120_1). For better comprehension, the DAC in the ADC-DAC set (e.g., the ADC-DAC set comprising the ADC and the DAC within the SAR ADC) of the aforementioned any stage 110_k may be implemented as a capacitive DAC, such as a DAC equipped with a series of capacitors on internal signal paths of the DAC, for generating the DAC output corresponding to the digital code D(k) in any cycle among multiple cycles, allowing the SAR ADC to perform signal comparison accordingly and selectively add or subtract a reference level to/from the current DAC output voltage in a next cycle, but the present invention is not limited thereto. The DAC in the ADC-DAC set may be implemented by way of any type of DAC among various types of DACs, such as the DAC equipped with a series of DAC elements (e.g., resistors or capacitors or current sources) belonging to a predetermined DAC element type (e.g., resistive type or capacitive type or current-source type) on internal signal paths of the DAC, for generating the DAC output corresponding to the digital code D(k) in any cycle among the multiple cycles.

Taking the capacitive DAC as an example of the DAC in the ADC-DAC set of the aforementioned any stage 110_k, the interstage gain error detection circuit corresponding to the stage index k may comprise (N(k)+1) circuit units 130_k (e.g., (N1+1) circuit units 130_1, for the case of k=1) of (N(k)+1) predetermined circuit elements (which may be either passive circuit elements or active circuit elements), with each predetermined circuit element being an identical element (e.g., an identical DAC element, such as a resistor or a capacitor or a current source) which is identical to a series of predetermined elements (e.g., the series of DAC elements, such as the resistors or the capacitors or the current sources) belonging to a predetermined element type (e.g., the predetermined DAC element type) within the aforementioned any stage 110_k. More particularly, for the aforementioned any stage 110_k (e.g., the stage 110_1) among the multiple stages {110_k}, the pipelined ADC 100 may utilize the (N(k)+1) circuit units 130_k (e.g., the (N1+1) circuit units 130_1) to start coupling the (N(k)+1) predetermined circuit elements to the input node and the output node of the amplifier 120_k (e.g., the amplifier 120_1) in turn, and, during coupling them to these nodes in turn, utilize multiple sub-circuits of the multiple circuit units to dynamically change the coupling relationships of the (N(k)+1) predetermined circuit elements.

In addition, the interstage gain error detection circuit corresponding to the stage index k may comprise (N(k)+1) analog multiplexing circuits respectively integrated into the (N(k)+1) circuit units 130_k (e.g., the (N1+1) circuit units 130_1, for the case of k=1). Among the (N(k)+1) analog multiplexing circuits, each analog multiplexing circuit may comprise at least one analog multiplexer (MUX) (e.g., two analog MUXs SW1(k) and SW2(k), such as the analog MUXs SW1(1) and SW2(1) if k=1, respectively labeled “SW1” and “SW2” for brevity) coupled with a corresponding predetermined circuit element (e.g., a corresponding capacitor C(k), such as a corresponding capacitor C(1) if k=1, labeled “C1” for brevity) among the (N(k)+1) predetermined circuit elements in series, and therefore the aforementioned at least one analog MUX such as the two analog MUXs SW1(k) and SW2(k) may be referred to as the two series analog MUXs SW1(k) and SW2(k). More particularly, during coupling the (N(k)+1) predetermined circuit elements to the input node and the output node of the amplifier 120_k (e.g., the amplifier 120_1) in turn, the pipelined ADC 100 may utilize the (N(k)+1) analog multiplexing circuits to control signal paths of the (N(k)+1) predetermined circuit elements by coupling one of the (N(k)+1) predetermined circuit elements to the input node of the amplifier 120_k while coupling the N(k) remaining predetermined circuit elements among the (N(k)+1) predetermined circuit elements to the output node of the amplifier 120_k at a same time point among multiple time points, for detecting the interstage gain error according to circuit element configurations corresponding to the multiple time points, where the (N(k)+1) predetermined circuit elements may act as the aforementioned one of the (N(k)+1) predetermined circuit elements at the multiple time points, respectively.

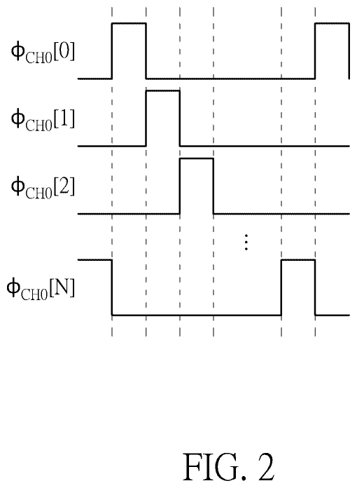

FIG. 2 illustrates multiple predetermined selection signals involved with the infinite-precision detection according to an embodiment of the present invention. The multiple predetermined selection signals may comprise (N(k)+1) selection signals φ_{CH(k-1)}[N(k):0] corresponding to the stage index k, such as the (N1+1) selection signals φ_{CH0}[N1:0] (for the case of k=1), which may be illustrated as the zeroth (0^{th}) selection signal φ_{CH0}[0], the first (1^{st}) selection signal φ_{CH0}[1], the second (2^{nd}) selection signal φ_{CH0}[2] . . . and the N1-th (N1^{th}) selection signal φ_{CH0}[N1] (labeled “φCH₀[N]” for brevity). The aforementioned at least one analog MUX (e.g., the two analog MUXs SW1(k) and SW2(k) such as the analog MUXs SW1 and SW2) may be arranged to choose the input or output connection of the corresponding predetermined circuit element (e.g., the corresponding capacitor C(k) such as the corresponding capacitor C1), depending on a predetermined selection signal φ_{CH(k-1)}[ ] such as the predetermined selection signal φ_{CH0}[ ]. More particularly, the predetermined selection signal φ_{CH(k-1)}[ ] such as the predetermined selection signal φ_{CH0}[ ] represents one of the (N(k)+1) selection signals φ_{CH(k-1)}[N(k):0] (e.g., the (N1+1) selection signals φ_{CH0}[N1:0], for the case of k=1) which are non-overlapping periodic signals. As shown in FIG. 2, the (N(k)+1) selection signals φ_{CH(k-1)}[N(k):0] such as the (N1+1) selection signals φ_{CH0}[N1:0] may be implemented as narrow pulse clocks, and may act as a series of chopping clocks.

Among the aforementioned at least one analog MUX of the pipelined ADC 100 shown in FIG. 1, the analog MUX SW1(k) such as the analog MUX SW1 may be arranged to selectively couple the output node of the corresponding predetermined circuit element (e.g., the corresponding capacitor C(k) such as the corresponding capacitor C1) to either the input node or the output node of the amplifier 120_k (e.g., the amplifier 120_1) according to the predetermined selection signal φ_{CH(k-1)}[ ] such as the predetermined selection signal φ_{CH0}[ ], and the analog MUX SW2(k) such as the analog MUX SW2 may be arranged to selectively couple the input node of the corresponding predetermined circuit element (e.g., the corresponding capacitor C(k) such as the corresponding capacitor C1) to either a correlator signal PN(k) (e.g., the correlator signal PN(1), labeled “PN1” for brevity) or an inverted signal PN(k)b (e.g., the inverted signal PN(1)b, labeled “PN1b” for brevity) of the correlator signal PN(k) according to the predetermined selection signal φ_{CH(k-1)}[ ] such as the predetermined selection signal φ_{CH0}[ ].

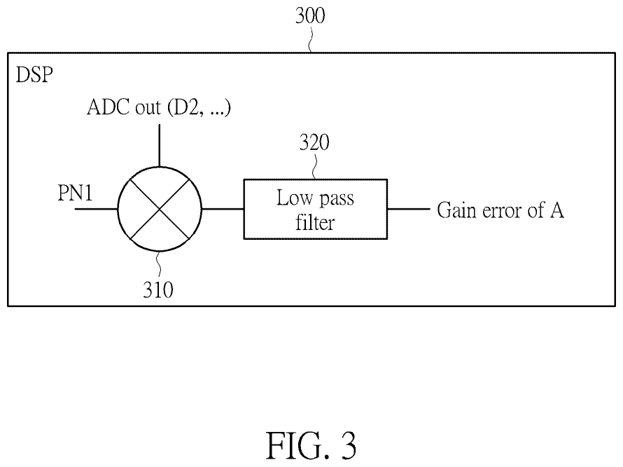

FIG. 3 illustrates a DSP circuit 300 involved with the infinite-precision detection according to an embodiment of the present invention. The DSP circuit 300 may comprise multiple sub-circuits such as a multiplying circuit 310 and a low pass filter 320. By coupling the (N(k)+1) predetermined circuit elements to the input node and the output node of the amplifier the amplifier 120_k in turn for at least one iteration, the pipelined ADC 100 can utilize the DSP circuit 300 to perform post processing according to the ADC output data {D(k+1), . . . }, in order to determine the interstage gain error. Taking the case of k=1 as an example, the post processing may comprise multiplying, by using the multiplying circuit 310, the ADC output data {D(k+1), . . . } such as the ADC output data {D(2), . . . } (labeled “ADC out (D2, . . . )” for brevity) with the correlator signal PN(k) such as the correlator signal PN1 to generate a multiplying calculation result, and may further comprise low pass filtering, by using the low pass filter 320, the result such as multiplying calculation result to get the gain error information (labeled “Gain error of A” for brevity).

In the pipeline of the pipelined ADC 100 shown in FIG. 1, the amplifier 120_k (e.g., the amplifier 120_1) is coupled between the two consecutive stages 110_k and 110_(k+1) (e.g., the two stages 110_1 and 110_2) among the multiple stages {110_k}, with the two consecutive stages 110_k and 110_(k+1) comprising the aforementioned any stage 110_k and the other stage 110_(k+1), and the other stage 110_(k+1) comes after the aforementioned any stage 110_k, where the gain A of the amplifier 120_k can be referred to as the interstage amplifier gain A of the amplifier 120_k. The interstage amplifier gain A of the amplifier 120_k (e.g., the amplifier 120_1) is ideally equal to N(k) (e.g., N1, for the case of k=1), that is, the circuit unit count (N(k)+1) (or the selection signal count (N(k)+1)) minus one, but it may suffer from random mismatch between the (N(k)+1) predetermined circuit elements. With the aid of the aforementioned interstage gain error detection circuit corresponding to the stage index k (or “the k-th detection circuit”), such as the detection circuit comprising the (N(k)+1) circuit units 130_k, the pipelined ADC 100 can determine the amplification parameter(s) (e.g., the interstage gain and/or the interstage gain error) of the amplifier 120_k (e.g., the amplifier 120_1) accurately, without any problem such as the problems due to inaccurate amplification in the related art.

The analog chopping technique such as the technique of using the (N(k)+1) selection signals φ_{CH(k-1)}[N(k):0] (e.g., the (N1+1) selection signals φ_{CH0}[N1:0], for the case of k=1) in the method can improve the detection accuracy beyond the device matching. In the CAP DAC example of the pipelined ADC 100 as shown in FIG. 1, to detect an interstage amplifier gain A=N1 in the case of k=1, the (N1+1) circuit units 130_1 such as the (N1+1) capacitive units, each comprising a capacitor C1, are prepared with the two series analog MUXs SW1 and SW2. The two series analog SW1 and SW2 are controlled by the (N1+1) selection signals φ_{CH0}[N1:0] acting as the series of chopping clock. For example, the gains {G1, G2, G3, . . . } of the amplifier 120_1 can be calculated as follows:

$$\begin{matrix}G 1 = ( N 1 * C 1 ) + ( ( Δ {C}_{2} + Δ {C}_{3} + … + Δ {C}_{N 1 + 1} ) / ( C 1 + Δ C 1 ) ) ; \\ G 2 = ( N 1 * C 1 ) + ( ( Δ {C}_{1} + Δ {C}_{3} + … + Δ {C}_{N 1 + 1} ) / ( C 1 + Δ C 2 ) ) ; \\ G 3 = ( N 1 * C 1 ) + ( ( Δ {C}_{1} + Δ {C}_{2} + … + Δ {C}_{N 1 + 1} ) / ( C 1 + Δ C 3 ) ) ; \\ …\end{matrix}$$

where the above gains {G1, G2, G3, . . . } can be obtained according to the circuit element configurations corresponding to the multiple time points (e.g., the time points in the (N1+1) phases of the (N1+1) selection signals φ_{CH0}[N1:0] within the same period, as indicated by the intervals depicted with vertical dashed lines in FIG. 2), respectively. For better comprehension, without chopping, the detected gain is approximately equal to (N1*(1+(\sqrt{2}*σ_{C1})). With chopping, the detected gain is approximately equal to (N1*(1+σ_{C1}²). With redundancy, the detection error can converge to zero.

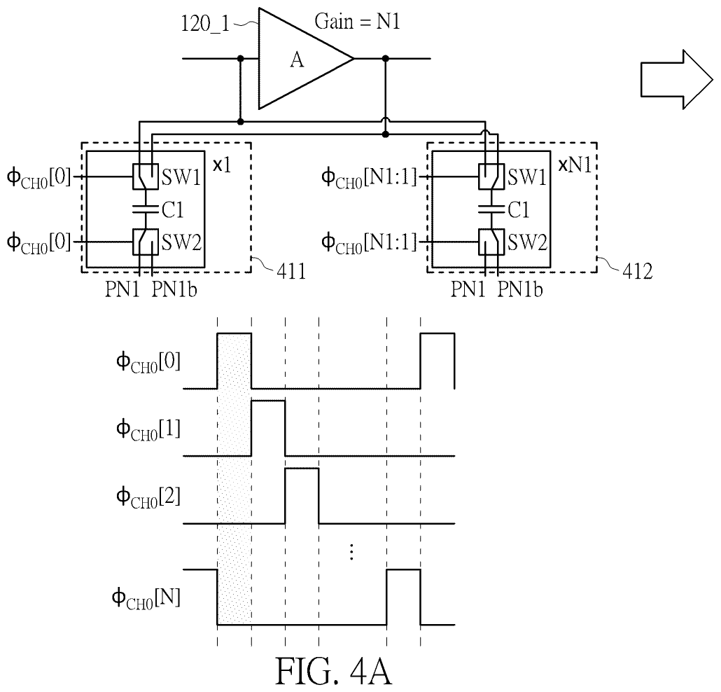

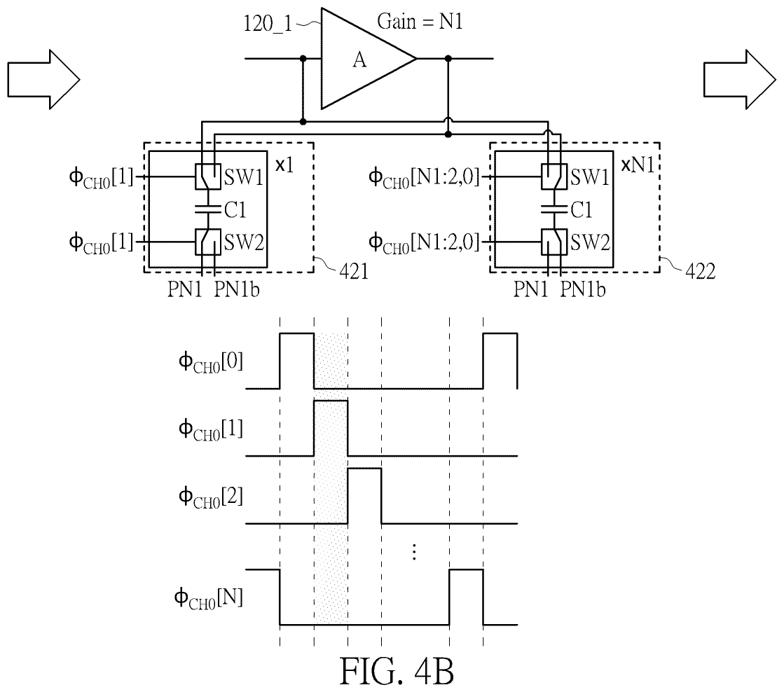

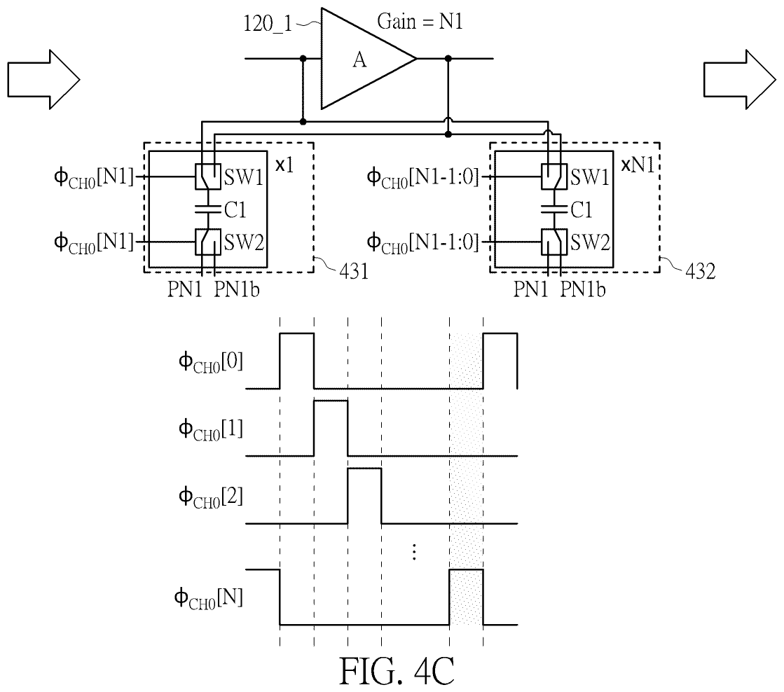

FIG. 4A, FIG. 4B, and FIG. 4C illustrate the zeroth phase, the first phase, and the N-th phase (e.g., the N1-th phase) among multiple phases of an analog chopping control scheme of the method according to an embodiment of the present invention, respectively, where the analog chopping technique mentioned above can be described with the analog chopping control scheme. The multiple phases may comprise the (N1+1) phases of the (N1+1) selection signals φ_{CH0}[N1:0] within the same period, as indicated by the intervals depicted with vertical dashed lines in FIG. 2. Taking case of k=1 as an example, the (N(k)+1) circuit units 130_k such as the (N1+1) circuit units 130_1 can have a zeroth circuit element configuration corresponding to a zeroth time point in the zeroth phase as shown in FIG. 4A, and can have a first circuit element configuration corresponding to a first time point in the first phase as shown in FIG. 4B, and the rest can be deduced by analogy, in particular, as shown in FIG. 4A, the (N(k)+1) circuit units 130_k such as the (N1+1) circuit units 130_1 can have an N1-th circuit element configuration corresponding to an N1-th time point in the N-th phase (e.g., the N1-th phase).

In any circuit element configuration among these circuit element configurations corresponding to these time points in these phases (as shown in FIG. 4A, FIG. 4B and FIG. 4C), on the left side of the amplifier 120_1, one unit (e.g., one circuit unit with one DAC element) injects a correlator signal PN such as the correlator signal PN1, while on the right side of the amplifier 120_1, N1 units (e.g., N1 circuit units with N1 DAC element) inject a negative correlator signal −A*PN1 (or A*PN1b). For example, in the zeroth phase shown in FIG. 4A, on the left side of the amplifier 120_1, one circuit unit 411 injects the correlator signal PN1, while on the right side of the amplifier 120_1, N1 circuit units 412 inject the negative correlator signal −A*PN1 (or A*PN1b); in the first phase shown in FIG. 4B, on the left side of the amplifier 120_1, one circuit unit 421 injects the correlator signal PN1, while on the right side of the amplifier 120_1, N1 circuit units 422 inject the negative correlator signal −A*PN1 (or A*PN1b); . . . and in the N-th phase (e.g., the N1-th phase) shown in FIG. 4C, on the left side of the amplifier 120_1, one circuit unit 431 injects the correlator signal PN1, while on the right side of the amplifier 120_1, N1 circuit units 432 inject the negative correlator signal −A*PN1 (or A*PN1b). Additionally, the set of MUX selection signals φ_{CH0}[N1:0] chooses one of the (N1+1) units on the left side, and these MUX selection signals φ_{CH0}[N1:0] are non-overlapping and their timings are shown in the timing diagrams in the respective lower half parts of FIG. 4A, FIG. 4B and FIG. 4C.

In the above embodiments, the case of k=1 can be taken as an example. This is for illustrative purposes only, and is not meant to be a limitation of the present invention. According to some embodiments, regarding the case of k>1, the rest can be deduced by analogy.

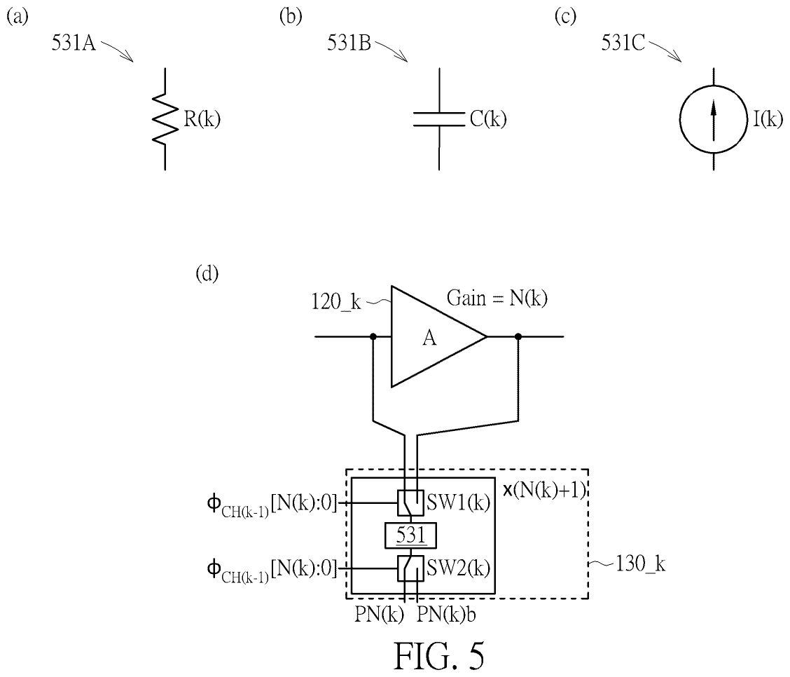

FIG. 5 illustrates, in the sub-diagram (d) thereof, a detection circuit involved with the method according to an embodiment of the present invention, where some examples of an identical DAC element used by a DAC unit among multiple DAC units of the detection circuit are illustrated in the sub-diagrams (a), (b), and (c) of FIG. 5 for better comprehension. The detection circuit may comprise the (N(k)+1) circuit units 130_k, and the (N(k)+1) predetermined circuit elements within the (N(k)+1) circuit units 130_k may comprise the (N(k)+1) predetermined circuit elements {531}. For example, the identical DAC element may be implemented as the identical DAC element 531A such as the resistor R(k) as shown in the sub-diagram (a). For another example, the identical DAC element may be implemented as the identical DAC element 531B such as the capacitor C(k) as shown in the sub-diagram (b). For yet another example, the identical DAC element may be implemented as the identical DAC element 531C such as the current source I(k) as shown in the sub-diagram (c). For brevity, similar descriptions for this embodiment are not repeated in detail here.

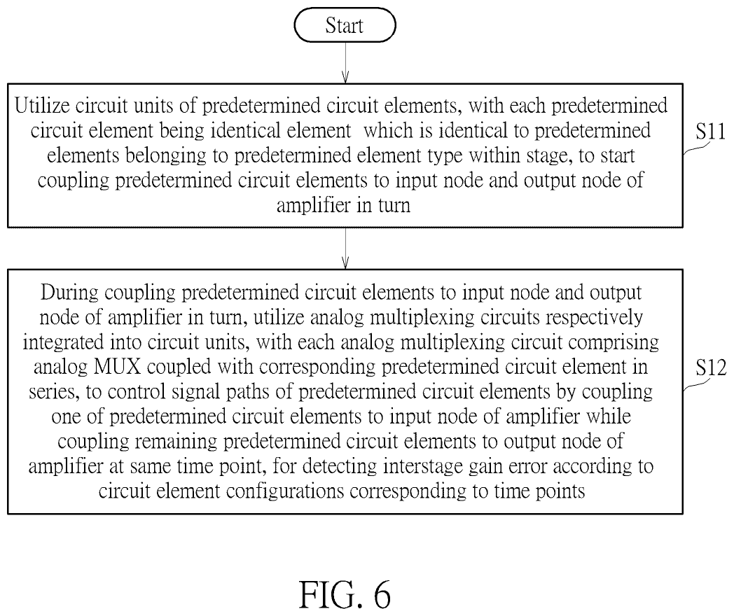

FIG. 6 illustrates a flowchart of the method according to an embodiment of the present invention. The pipelined ADC 100 may operate according to the working flow shown in FIG. 6.

In Step S11, for the aforementioned any stage 110_k among the multiple stages {110_k}, the pipelined ADC 100 may utilize the (N(k)+1) circuit units 130_k of the (N(k)+1) predetermined circuit elements {531}, with each predetermined circuit element 531 being an identical element which is identical to the series of predetermined elements belonging to the predetermined element type within the aforementioned any stage 110_k, to start coupling the (N(k)+1) predetermined circuit elements {531} to the input node and the output node of the amplifier 120_k (e.g., the amplifier 120_1) in turn. For example, the series of predetermined elements may represent the series of DAC elements such as the resistors or the capacitors or the current sources, and the identical element may represent the identical DAC element 531A/531B/531C such as the resistor R(k) or the capacitor C(k) or the current source I(k), correspondingly, identical to the series of DAC elements.

In Step S12, during coupling the (N(k)+1) predetermined circuit elements {531} to the input node and the output node of the amplifier 120_k in turn, the pipelined ADC 100 may utilize the (N(k)+1) analog multiplexing circuits respectively integrated into the (N(k)+1) circuit units 130_k, with each analog multiplexing circuit comprising at least one analog MUX (e.g., the two analog MUXs SW1(k) and SW2(k)) coupled with a corresponding predetermined circuit element 531 among the (N(k)+1) predetermined circuit elements {531} in series, to control signal paths of the (N(k)+1) predetermined circuit elements {531} by coupling one of the (N(k)+1) predetermined circuit elements {531} to the input node of the amplifier 120_k while coupling the N(k) remaining predetermined circuit elements among the (N(k)+1) predetermined circuit elements {531} to the output node of the amplifier 120_k at a same time point among multiple time points, for detecting the interstage gain error according to circuit element configurations corresponding to the multiple time points, where the (N(k)+1) predetermined circuit elements may act as the aforementioned one of the (N(k)+1) predetermined circuit elements at the multiple time points, respectively.

For example, when the series of DAC elements are implemented as the resistors and the identical element is implemented as the identical DAC element 531A such as the resistor R(k), the corresponding predetermined circuit element 531 may represent a corresponding resistor R(k). For another example, when the series of DAC elements are implemented as the capacitors and the identical element is implemented as the identical DAC element 531B such as the capacitor C(k), the corresponding predetermined circuit element 531 may represent a corresponding capacitor C(k). For yet another example, when the series of DAC elements are implemented as the current sources and the identical element is implemented as the identical DAC element 531C such as the current source I(k), the corresponding predetermined circuit element 531 may represent a corresponding current source I(k).

As there are the multiple stages {110_k} such as the stages {110_k|k=1, 2, . . . , K}, when k=1, the aforementioned any stage 110_k may represent the stage 110_1, and the (N(k)+1) circuit units 130_k may represent the (N1+1) circuit units 130_1, where the two analog MUXs SW1(k) and SW2(k) may represent the analog MUXs SW1(1) and SW2(1); when k=2, the aforementioned any stage 110_k can represent the stage 110_2, and the (N(k)+1) circuit units 130_k can represent the (N2+1) circuit units 130_2, where the two analog MUXs SW1(k) and SW2(k) may represent the analog MUXs SW1(2) and SW2(2); and the rest can be deduced by analogy. For brevity, similar descriptions for this embodiment are not repeated in detail here.

For better comprehension, the method may be illustrated with the working flow shown in FIG. 6, but the present invention is not limited thereto. According to some embodiments, one or more steps may be added, deleted, or changed in the working flow shown in FIG. 6. For example, by coupling the (N(k)+1) predetermined circuit elements to the input node and the output node of the amplifier the amplifier 120_k in turn for the aforementioned at least one iteration (e.g., one or more iterations corresponding to one or more common periods of the (N(k)+1) selection signals φ_{CH(k-1)}[N(k):0]), the pipelined ADC 100 can utilize the DSP circuit 300 to perform the post processing according to the ADC output data {D(k+1), . . . }, in order to determine the interstage gain error. In addition, after the associated operations of the aforementioned any stage 110_k are completed, the pipelined ADC 100 can perform similar operations for any other stage such as the next stage, and more particularly, can increase the stage index k with a predetermined increment such as one, in order to perform the operations of the next stage. For brevity, similar descriptions for these embodiments are not repeated in detail here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for detecting an interstage gain error of a pipelined analog-to-digital converter (ADC) with infinite precision, the pipelined ADC comprising multiple stages in a pipeline of the pipelined ADC, the method comprising:
for any stage among the multiple stages, utilizing multiple circuit units of predetermined circuit elements, with each predetermined circuit element being an identical element which is identical to a series of predetermined elements belonging to a predetermined element type within the any stage, to start coupling the predetermined circuit elements to an input node and an output node of an amplifier, the amplifier coupled between the any stage and another stage, in turn; and
during coupling the predetermined circuit elements to the input node and the output node of the amplifier in turn, utilizing multiple analog multiplexing circuits respectively integrated into the multiple circuit units, with each analog multiplexing circuit comprising at least one analog multiplexer (MUX) coupled with a corresponding predetermined circuit element among the predetermined circuit elements in series, to control signal paths of the predetermined circuit elements by coupling one of the predetermined circuit elements to the input node of the amplifier while coupling remaining predetermined circuit elements among the predetermined circuit elements to the output node of the amplifier at a same time point among multiple time points, for detecting the interstage gain error according to circuit element configurations corresponding to the multiple time points, wherein the predetermined circuit elements act as the one of the predetermined circuit elements at the multiple time points, respectively.

2. The method of claim 1, wherein the predetermined circuit elements are either passive circuit elements or active circuit elements.

3. The method of claim 1, wherein the identical element represents a resistor or a capacitor or a current source.

4. The method of claim 1, wherein the at least one analog MUX comprises a first analog MUX, for selectively coupling an output node of the corresponding predetermined circuit element to either the input node or the output node of the amplifier.

5. The method of claim 4, wherein the at least one analog MUX further comprise a second analog MUX, for selectively coupling an input node of the corresponding predetermined circuit element to either a correlator signal or an inverted signal of the correlator signal.

6. The method of claim 5, wherein the first analog MUX is arranged to selectively couple the output node of the corresponding predetermined circuit element to either the input node or the output node of the amplifier according to a predetermined selection signal; and the second analog MUX is arranged to selectively couple the input node of the corresponding predetermined circuit element to either the correlator signal or the inverted signal of the correlator signal according to the predetermined selection signal.

7. The method of claim 4, wherein the first analog MUX is arranged to selectively couple the output node of the corresponding predetermined circuit element to either the input node or the output node of the amplifier according to a predetermined selection signal.

8. The method of claim 1, wherein the at least one analog MUX is arranged to choose input or output connection of the corresponding predetermined circuit element, depending on a predetermined selection signal.

9. The method of claim 8, wherein the predetermined selection signal represents one of multiple predetermined selection signals which are non-overlapping periodic signals.

10. The method of claim 9, wherein the multiple predetermined selection signals are implemented as narrow pulse clocks.

11. The method of claim 1, wherein the pipelined ADC is a pipelined successive approximation register (SAR) ADC, and the any stage among the multiple stages comprises a SAR ADC, wherein the series of predetermined elements is within the SAR ADC of the any stage.

12. The method of claim 11, wherein the SAR ADC of the any stage comprises an ADC and a digital-to-analog converter (DAC), wherein the series of predetermined elements is within the DAC; and the series of predetermined elements represents a series of DAC elements, the predetermined element type represents a predetermined DAC element type, and said each predetermined circuit element is an identical DAC element which is identical to the series of DAC elements belonging to the predetermined DAC element type within the any stage.

13. The method of claim 1, wherein the amplifier is coupled between two consecutive stages among the multiple stages, with the two consecutive stages comprising the any stage and the other stage, and the other stage comes after the any stage.

14. A detection circuit for detecting an interstage gain error of a pipelined analog-to-digital converter (ADC) with infinite precision, the pipelined ADC comprising multiple stages in a pipeline of the pipelined ADC, for any stage among the multiple stages, the detection circuit comprising:
multiple circuit units of predetermined circuit elements, the multiple circuit units comprising:
the predetermined circuit elements, with each predetermined circuit element being an identical element which is identical to a series of predetermined elements belonging to a predetermined element type within the any stage; and
multiple analog multiplexing circuits, respectively integrated into the multiple circuit units, with each analog multiplexing circuit comprising at least one analog multiplexer (MUX) coupled with a corresponding predetermined circuit element among the predetermined circuit elements in series;
wherein:
for the any stage among the multiple stages, the multiple circuit units are arranged to start coupling the predetermined circuit elements to an input node and an output node of an amplifier, the amplifier coupled between the any stage and another stage, in turn; and
during coupling the predetermined circuit elements to the input node and the output node of the amplifier in turn, the multiple analog multiplexing circuits are arranged to control signal paths of the predetermined circuit elements by coupling one of the predetermined circuit elements to the input node of the amplifier while coupling remaining predetermined circuit elements among the predetermined circuit elements to the output node of the amplifier at a same time point among multiple time points, for detecting the interstage gain error according to circuit element configurations corresponding to the multiple time points, wherein the predetermined circuit elements act as the one of the predetermined circuit elements at the multiple time points, respectively.
